(19) United States
(12) Patent Application Publication
(10) Pub. No.: US 2010/0134998 A1
(43) Pub. Date: Jun. 3, 2010

(54) Adapter, socket, electronic device, and mounting method

(75) Inventors: Goro Kiyota, Tokyo (JP); Shotaro Kobayashi, Tokyo (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: ELPIDA MEMORY, INC., Tokyo (JP)

(21) Appl. No.: 12/320,936

(22) Filed: Feb. 9, 2009

(30) Foreign Application Priority Data
Dec. 2, 2008 (JP) 2008-029951

(51) Int. Cl. H05K 7/12

(52) U.S. Cl. 361/808

(57) ABSTRACT

An adapter has a body having a plate-like shape, a holding portion which holds the semiconductor package on a first surface of the body to be electrically connected to terminals of the semiconductor package, and first terminals provided on a second surface of the body and electrically connected to the fitting portions. The adapter is designed mountable to a board via a socket by inserting the first terminals into the socket.

This application is based upon and claims the benefit of priority from Japanese patent application No. 2008-29951, filed on Feb. 12, 2008, the disclosure of which is incorporated herein in its entirety by reference.

### BACKGROUND OF THE INVENTION

The present invention relates to an adapter for mounting a semiconductor package such as a TSOP (Thin Small Outline Package) type package having plate-shaped terminals, by means of a socket. The invention also relates to a socket for use in mounting such a semiconductor package, an electronic device having such a semiconductor package mounted thereon, and a method of mounting such a semiconductor package.

Electronic devices having various components such as semiconductor packages mounted on a motherboard or the like are sometimes tested to find defects by once removing the mounted semiconductor packages and remounting them.

When removing a semiconductor package to be tested, not only the package but also the electronic device itself will be subjected to mechanical stress and heat, possibly resulting in destruction of the electronic device itself.

To avoid this, in some cases, a semiconductor package is mounted via a socket instead of directly mounted on a board.

In a BGA (Ball Grid Array) package, for example, contact members are provided on the rear surface of a package. This type of package has such configuration that the socket size can be reduced easily, and hence various types of sockets have been placed on market (see, for example, “Grypper™—High Performance BGA Socket”, [online] 2008, Gryphics, [found Jan. 31, 2008 on Internet URL:http://www.cascademicrotech.com/go/production-products-division/gryphics-sockets/grypper/]).

Further, there are known removable sockets developed for a package, such as a TSOP (Thin Small Outline Package) type package, in which plate-shaped terminals are provided on side faces of a package, (see, for example, Japanese Laid-Open Utility Model Publication No. H05-73948).

The present inventors have recognized that, in the case of a semiconductor package such as a TSOP type package using plate-shaped terminals, the size of a socket cannot be reduced as much as in a BGA type package due to the shape of the package. The present inventors further have recognized that the socket cannot be attached to recent small-sized electronic devices or electronic devices having densely mounted components and that it difficult to achieve mounting of the package using the socket.

### SUMMARY

The present invention seeks to solve one or more of the above problems, or to improve upon those problems at least in part.

In first embodiment, there is provided an adapter that is for mounting a semiconductor package having plate-shaped terminals on a board by means of a socket. This adapter includes an adapter body having a plate like shape, a holding portion which holds the semiconductor package on a first surface of the adapter body to be connected to the terminals of the semiconductor package, and first terminals provided on a second surface of the adapter body and electrically connected to the holding portion. The adapter is designed mountable on the board via the socket by inserting the first terminals into the socket.

In second embodiment, there is provided a socket that is provided on a board for mounting the adapter according to the first embodiment on the board. The socket includes second terminals provided on a first surface of a socket body to be electrically connected to the first terminals of the adapter; and third terminals electrically connected to the second terminals and connectable to the board.

In third embodiment, there is provided an electronic device that includes a semiconductor package having plate-shaped terminals; an adapter arranged to be electrically connectable to the semiconductor package; a socket arranged to be electrically connectable to the adapter; and a board arranged to be electrically connectable to the socket. The adapter includes a holding portion which holds the semiconductor package on a first surface of the adapter body to be electrically connected to the terminals of the semiconductor package, and first terminals provided on a second surface of the adapter body and electrically connected to the holding portion. The socket has second terminals provided on a first surface of a socket body and electrically connected to the first terminals of the adapter, and third terminals provided on a second surface of the socket body and electrically connected to the second terminals and connectable to the board.

In fourth embodiment, there is provided a method of mounting a semiconductor package having plate-shaped terminals on a board that uses the adapter according to the first embodiment. The method includes (a) holding the semiconductor package on the adapter to electrically connect the terminals of the semiconductor package to the holding portion of the adapter, and (b) mounting the adapter having the semiconductor package connected thereto on a socket provided on the board.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a cross-sectional view showing an electronic device 200 in an exploded state;

FIG. 2A is a perspective view of a package 1;

FIG. 2B is a perspective view of an adapter 3;

FIG. 2C is a perspective view of the rear surface of the adapter 3;

FIG. 2D is a perspective view of a socket 5;

FIG. 3 is a diagram showing only the package 1 and the adapter 3 as viewed in the direction of arrow C1 in FIG. 1;

FIG. 4 is an enlarged view of a hole-shaped terminal 27 shown in FIG. 1;

FIG. 5 is a diagram showing a step during mounting of the package 1 on a wiring board 100;

FIG. 6 is a diagram showing a step during mounting of the package 1 on the wiring board 100;

FIG. 7 is a diagram showing a step during mounting of the package 1 on the wiring board 100;

FIG. 8 is a cross-sectional view showing an electronic device 201 in an exploded state;

FIG. 9 is a perspective view showing a socket 5a;

FIG. 10 is a cross-sectional view showing an electronic device 202 in an exploded state;

FIG. 11A is a perspective view of the rear surface of an adapter 3b;

FIG. 11B is a perspective view showing a socket 45;

FIG. 12 is a perspective view showing a state in which the package 1, the adapter 3, and the socket 45 are assembled together;

FIG. 13 is a cross-sectional view showing an electronic device 203 in an exploded state;

FIG. 14A is a perspective view showing an adapter 3c;

FIG. 14B is a perspective view showing a modification of the adapter 3c;

FIG. 15 is a cross-sectional view showing a modification of the electronic device 203;

FIG. 16 is a perspective view showing the adapter 3c shown in FIG. 15;

FIG. 17 is a cross-sectional view showing an electronic device 204 in an exploded state;

FIG. 18A is an enlarged cross-sectional view showing an adapter 3d shown in FIG. 17;

FIG. 18B shows a modification of the adapter of FIG. 18A; and

FIG. 19 is a cross-sectional view showing another modification of the adapter 3d.

### DESCRIPTION OF THE EXEMPLARY EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposes.

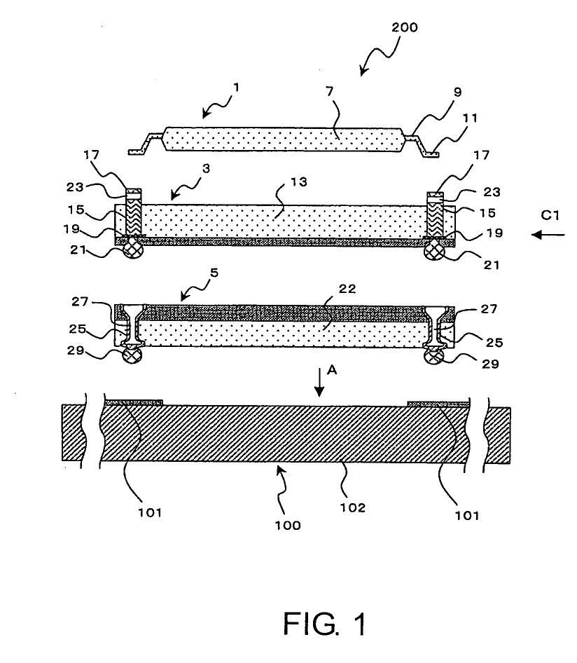

Referring now to FIG. 1, an electronic device 200 according to a first embodiment of the present invention includes a package 1 which is a semiconductor package such as a TSOP (Thin Small Outline Package) type package, an adapter 3 on which the package 1 can be mounted, a socket 5 on which the adapter 3 can be mounted, and a wiring board 100 on which the socket 5 can be mounted.

This means that, the electronic device 200 is formed by mounting the package 1 on the adapter 3 and mounting the adapter 3 on the wiring board 100 via the socket 5. The package 1 is electrically connected to the wiring board 100 though the adapter 3 and the socket 5.

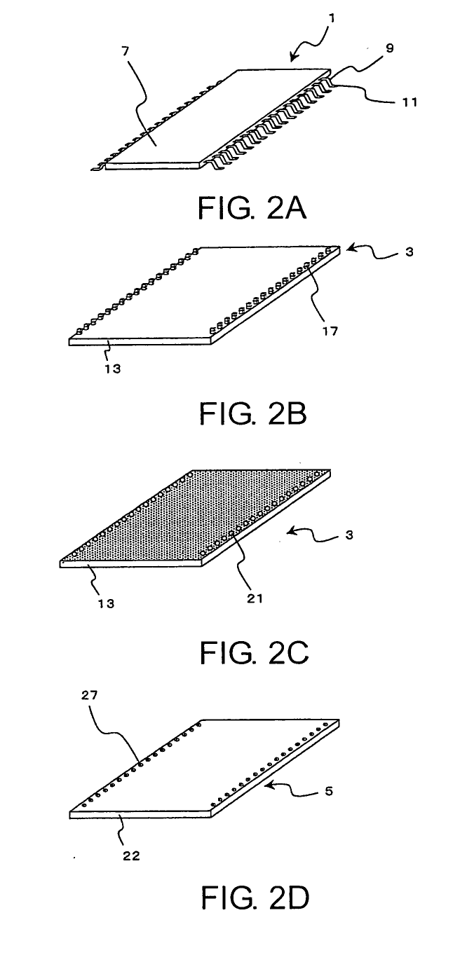

Next, referring to FIG. 1, FIGS. 2A to 2D, FIG. 3 and FIG. 4, detailed description will be made of configurations of the components of the electronic device 200, namely, the package 1, the adapter 3, the socket 5, and the wiring board 100.

First, description will be made of a configuration of the package 1.

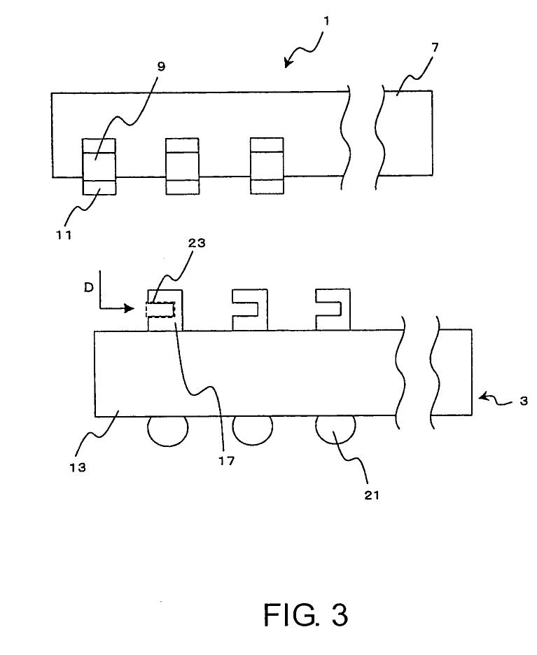

As shown in FIG. 1, FIG. 2A and FIG. 3, the package 1 has an elongated plate-shaped package body 7, and a plurality of plate-shaped connection terminals 9 are provided on the longitudinally opposite side faces of the package body 7 for electrically connecting the package 1 to another member. As mentioned in the above, the package 1 is a TSOP type package, for example.

Next, description will be made of a configuration of the adapter 3.

As shown in FIG. 1, FIG. 2B and FIG. 3, the adapter 3 has an elongated plate-shaped adapter body 13. The adapter body 13 has a longitudinal dimension corresponding to that of the package 1, and has a width dimension corresponding to the width dimension of the package 1 including the connection terminals 9.

The adapter body 13 is provided with through holes 15 passing through the adapter body 13. A pillar-shaped connection pin 17 made of a conductive material is provided as a connecting terminal of a holding portion within each of the through holes 15. An end of the connection pin 17 protrudes out of a first surface (upper surface) of the adapter body 13, and a cutout portion 23 is formed in a side face of the protruding part of the connection pin 17 to form a hook shape.

As shown in FIG. 3, each cutout portion 23 has a shape corresponding to the shape of the end portion 11 of a connection terminal 9 of the package 1, and the end portion 11 can be fit in the cutout portion 23, as described later. This means that the connection pins 17 not only are electrically connected to the connection terminals 9 but also fix the package body 7 to the adapter body 13. Thus, the holding portion not only holds the semiconductor package 1 on the first surface of the adapter 3 but connect the terminals 9 of the semiconductor package 1 with the connecting terminals of adapter 3.

As shown in FIG. 1 and FIG. 2C, solder balls 21 serving as first terminals are provided on a second surface (lower surface) of the adapter body 13, directly below the connection pins 17. The solder balls 21 are electrically connected to the connection pins 17 via the terminals 19.

Next, description will be made of a configuration of the socket 5.

As shown in FIG. 1 and FIG. 2D, the socket 5 has an elongated plate-shaped socket body 22. The socket body 22 has longitudinal and width dimensions corresponding to those of the adapter body 13. The socket body 22 is formed with through holes 25 passing through the socket body 22, and a hole-shaped terminal 27 made of a conductive material is provided as a second terminal within each of the through holes 25.

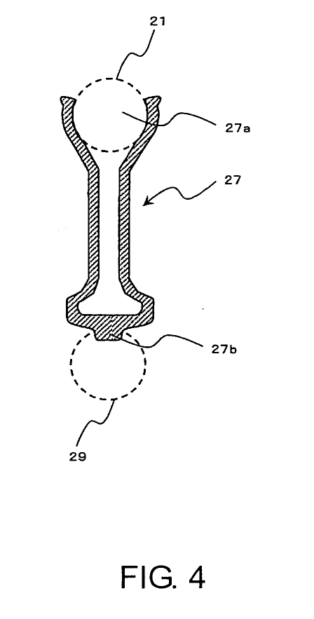

As shown in FIG. 4, an end of each hole-shaped terminal 27 on the side of a first surface (the surface facing the adapter 3, or the upper surface) of socket body 22 is formed in a cup shape defining an accommodating hole portion 27a. The accommodating hole portion 27a has a shape corresponding to that of the solder ball 21 of the adapter 3 and is connectable with the solder ball 21. This means that the hole-shaped terminals 27 not only fix the solder balls 21 but also electrically connect between the adapter 3 and the socket 5.

The other end of each hole-shaped terminal 27 on the side of a second surface (the surface facing the wiring board 100, or the rear surface) of the socket body 22 is formed with a convex-shaped connection portion 27b. The connection portion 27b is provided with a solder ball 29 as a third terminal. The solder balls 29 are electrically connectable to wiring lines 101 of the wiring board 100 as described later.

Next, description will be made on a configuration of the wiring board 100.

As shown in FIG. 1, the wiring board 100 has wiring lines 101 of copper or the like arranged on a substrate 102 made of glass epoxy or the like. The wiring board 100 is further designed such that other electronic devices (capacitors, resistors, and ICs) not shown in the figure can be mounted on.

Next, description will be made of steps during mounting of the package 1 on the wiring board 100 with reference to FIGS. 1 and 3 to 7.

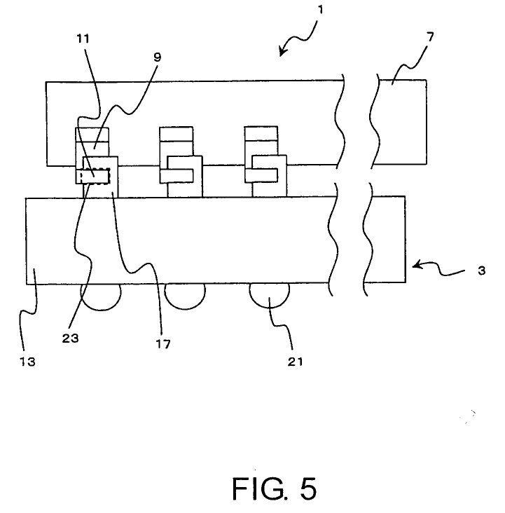

First, the package 1 is connected with the adapter 3. More specifically, the package 1 is moved in the direction as indicated by arrow D from the state shown in FIG. 3, so that the end portions 11 of the connection terminals 9 are slid and fit in the cutout portions 23 of the corresponding connection pins 17 of the adapter 3. In this manner, the package 1 and the adapter 3 are electrically connected as shown in FIG. 5.

On the other hand, the socket 5 is connected to the wiring board 100, in addition to the connection between the package 1 and the adapter 3. More specifically, the socket 5 is moved in the direction indicated by arrow A of FIG. 1 from the state shown in FIG. 1, so that the solder balls 29 are brought into contact with the wiring lines 101. Once the solder balls 29 are in contact with the wiring lines 101, the solder balls 29 are connected to the wiring lines 101 by reflow soldering or the like. Thus, the socket 5 and the wiring board 100 are electrically connected to each other.

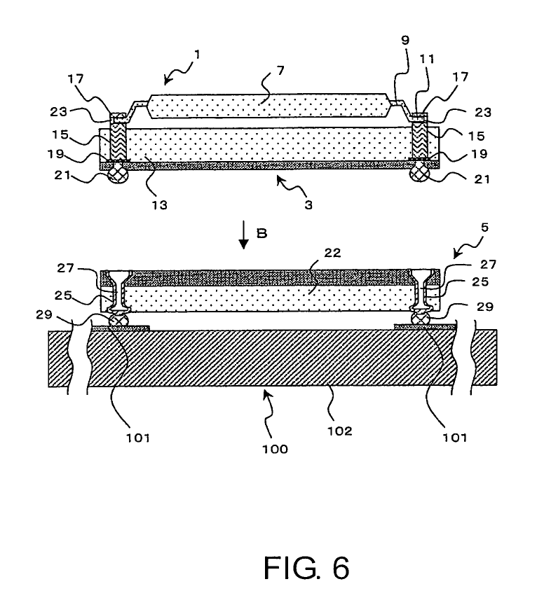

FIG. 6 shows the state at this time. Specifically, the package 1 and the adapter 3 are electrically connected, while the socket 5 is mounted on the wiring board 100.

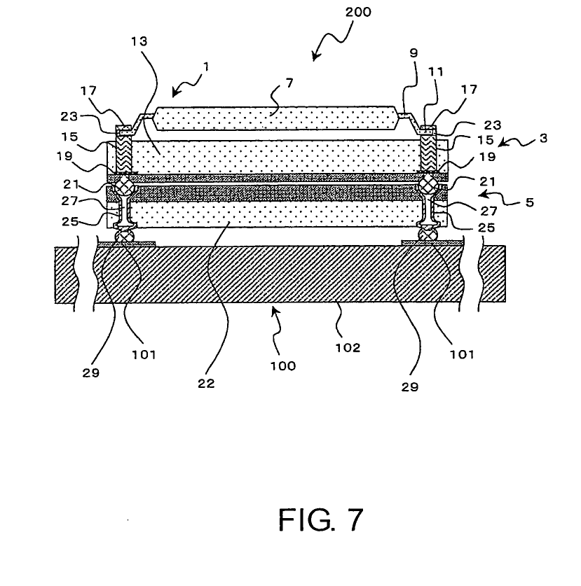

Next, the socket 5 is connected with the adapter 3. More specifically, the adapter 3 is moved together with the package 1 in the direction indicated by arrow B from the state as shown in FIG. 6, so that the solder balls 21 of the adapter 3 are inserted into the accommodating hole portions 27a of the hole-shaped terminals 27 of the socket 5 (see FIG. 4) and connected thereto in the same manner as fastening snap buttons. Thus, as shown in FIG. 7, the package 1 is connected (mounted) on the wiring board 100 via the adapter 3 and the socket 5.

As described above, the adapter 3 is provided with the connection pins 17 each having a cutout portion 23, and the package 1 is once connected to the adapter 3 before fitting the adapter 3 to the socket 5 so that the connection via the socket 5 is established. This means that the attachment between the package 1 and the adapter 3 is not performed directly on the electronic device itself (the wiring board 100), and hence the package 1 can be attached easily without any forcible manipulation. Accordingly, even if the position on the wiring board 100 where the package 1 is to be attached is surrounded closely by other devices, the package 1 can be easily attached to the wiring board 100 without being interfered by other devices in the vicinity thereof.

Further, the connection between the adapter 3 and the package 1 is performed by using the connection pins 17 each having the cutout portion 23, while the connection between the adapter 3 and the socket 5 is performed by fitting the solder balls 21 provided on the surface of the adapter body 13 into the accommodating hole portions 27a provided in the upper surface of the socket 5. This makes it possible to reduce the size of the socket 5 to a size corresponding to that of the package 1, that is, a size smaller than that of conventional sockets. Therefore, even if the package 1 is a TSOP type package having plate-shaped terminals, the package 1 can be attached, via the socket 5, to a small-sized electronic device or an electronic device having densely mounted electronic components.

Furthermore, if the package is remounted on the wiring board 100 according to a conventional method, the electronic device itself may be broken by significant damage caused by heat or mechanical factors during the removal or mounting of the package. In contrast, according to the embodiment, the remounting of the package can be achieved by only one step of removing the originally mounted package 1 and remounting the socket 5. Therefore, no damage is incurred to the electronic device itself (or the wiring board 100 and other devices mounted on the wiring board 100). Furthermore, the package 1 can be replaced easily and quickly once the socket 5 has been remounted.

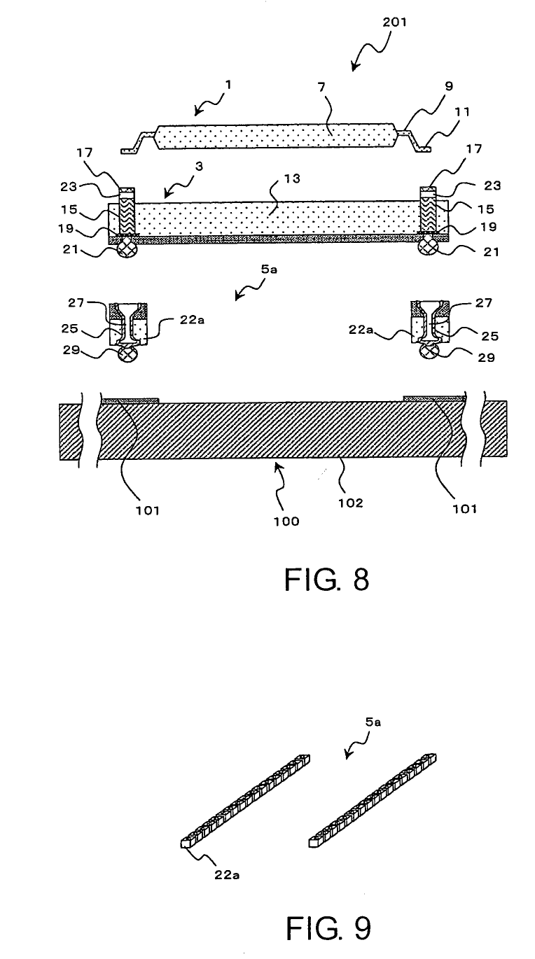

Next, a configuration of an electronic device 201 according to a second embodiment of the invention will be described with reference to FIGS. 8 and 9. In the description of the second embodiment below, elements having the same functions as those of the first embodiment are assigned with the same reference numerals and description thereof is omitted.

Referring to FIGS. 8 and 9, the electronic device 201 is different from the first embodiment in that a socket body 22a of a socket 5a is divided into a plurality of sections corresponding to the respective hole-shaped terminals 27. In this manner, the socket body 22a may be divided into a plurality of sections instead of being a single plate-shaped member.

According to the second embodiment, as described above, the electronic device 201 has a package 1 which is a semiconductor package such as a TSOP type package, an adapter 3, the socket 5a, and a wiring board 100, and is designed such that package 1 can be mounted on the wiring board 100 via the socket 5a after fitting the connection terminals 9 of the package 1 into the connection pins 17 of the adapter 3. As a result, the second embodiment provides beneficial effects similar to those of the first embodiment.

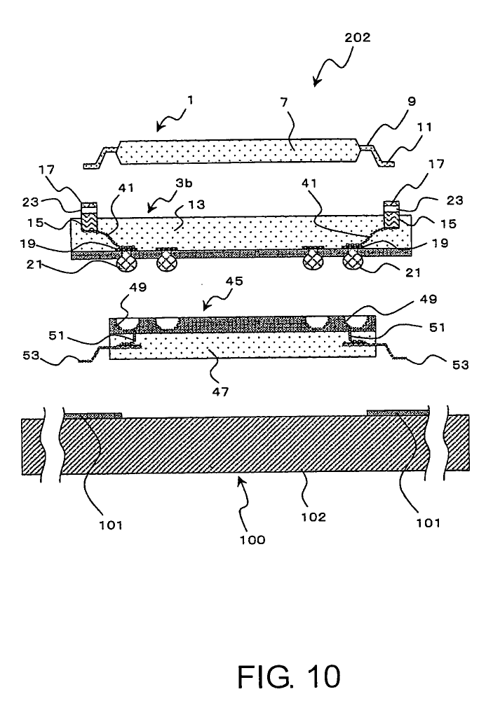

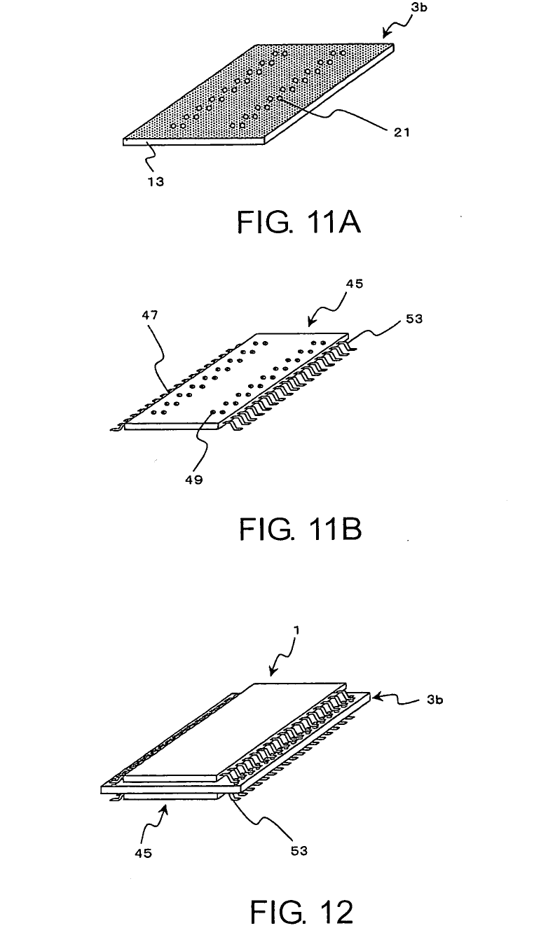

Next, an electronic device 202 according to a third embodiment will be described with reference to FIG. 10, FIGS. 11A and 11B, and FIG. 12. In the description of the third embodiment below, elements having the same functions as those of the first embodiment are assigned with the same reference numerals and description thereof is omitted.

The electronic device 202 is different from the first embodiment in that solder balls 21 of an adapter 3b are provided offset to the inside instead of being provided directly below the connection pins 17, and are connected to wiring lines 101 of a socket 45 by means of lead terminals 53.

As shown in FIGS. 10 and FIG. 11A, the adapter 3b has the solder balls 21 provided offset to the inside (to the center side) of an adapter body 13 instead of being provided directly below the connection pins 17. The solder balls 21 and the connection pins 17 are mutually electrically connected by internal wiring lines 41 provided within the adapter body 13.

Since the solder balls 21 must be spaced from each other by a certain distance, it becomes difficult to arrange the solder balls 21 directly below the connection pins 17 of the adapter 3 as in the first embodiment if the distance between the connection terminals 9 of the package 1 is not large enough. This problem can be avoided by offsetting the positions of the solder balls 21 to the inside, as shown in FIG. 10 and FIG. 11A, to ensure a sufficient distance therebetween. This allows arbitrary arrangement of the solder balls 21 without restriction of arrangement of the connection pins 17. For example, the solder balls 21 may be arranged in four lines.

On the other hand, as shown in FIG. 10 and FIG. 11B, the socket 45 has a socket body 47, and hole-shaped terminals 49 are arranged at positions corresponding to the solder balls 21 of the adapter 3b, on the upper surface (the surface facing the adapter 3b) of the socket body 47.

Further, as shown in FIG. 10, FIG. 11B, and FIG. 12, lead terminals 53 to be connected to the wiring board 100 are provided on the side faces of the socket body 47. The hole-shaped terminals 49 and the lead terminals 53 are mutually electrically connected by internal wiring lines 51 provided within the socket body 47. In this manner, the wiring board 100 and the socket 45 may be connected by means of the lead terminals 53 instead of solder balls.

According to the third embodiment, as described above, the electronic device 202 has the package 1 which is a semiconductor package such as a TSOP type package, the adapter 3b, the socket 45, and the wiring board 100, and is designed such that the package 1 can be mounted on the wiring board 100 via the socket 5a after fitting the connection terminals 9 into the connection pins 17 of the adapter 3b. As a result, the third embodiment provides beneficial effects similar to those of the first embodiment.

Further, according to the third embodiment, the adapter 3b has solder balls 21 arranged offset to the inside of the adapter body 13, instead of being arranged directly below the connection pins 17, while the lead terminal 53 to be connected to the wiring board 100 are arranged on the side faces of the socket body 47. Therefore, sufficient intervals can be ensured between the solder balls 21 even if the spacing between the connection terminals 9 of the package 1 is as small as making it difficult to arrange the solder balls 21 directly below the connection pins 17 of the adapter 3.

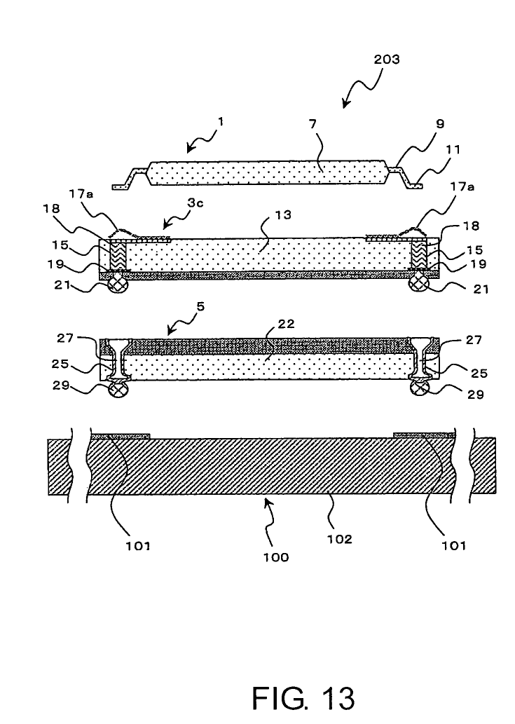

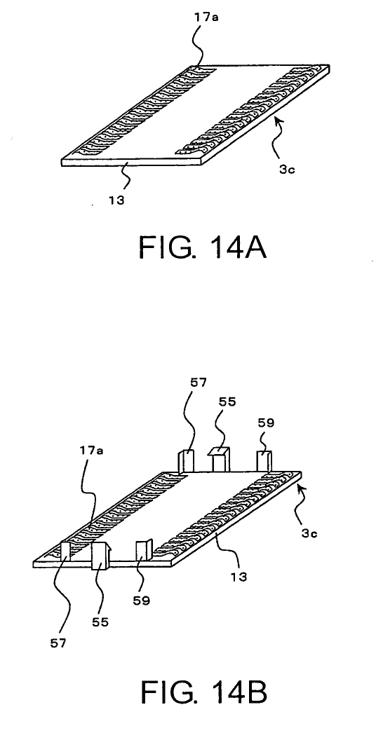

Next, a fourth embodiment will be described with reference to FIG. 13, FIGS. 14A and 14B, FIG. 15, and FIG. 16. In the description of the fourth embodiment below, elements having the same functions as those of the first to third embodiments are assigned with the same reference numerals and description thereof is omitted.

The fourth embodiment is different from the first embodiment in that an adapter 3c is provided with connection pins 17a which have a plate-like shape curved upward, instead of a pillar-like shape provided with a cutout portion in a side face thereof.

As shown in FIG. 13 and FIG. 14A, the adapter 3c has, on the upper surface of the adapter body 13, plate-shaped connection pins 17a curved upward (in the direction towards the package 1), as plate terminals. These connection pins 17a are arranged at positions corresponding to the connection terminals 9.

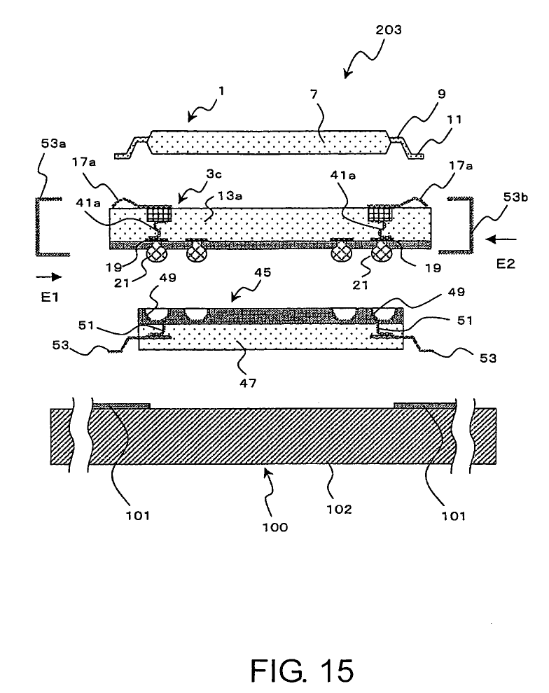

The connection pin 17a and the solder ball 21 are mutually electrically connected by means of terminals 18 provided in through holes 15 and terminals 19. Alternatively, the connection between the connection pins 17a and the solder balls 21 may be performed by means of internal wiring lines 41a as shown in FIG. 15.

In this manner, the connection pins 17a may have a shape like a curved plate. This shape of the connection pins 17a makes it possible to set the spacing between the connection pins 17a smaller than that of the first embodiment, and hence makes it possible to electrically connect the package 1 to the adapter 3c even if the spacing between the connection terminals 9 of the package 1 is as small as making it difficult to connect the connection terminals 9 to the connection pins 17 if the connection pins 17 are shaped according to the first embodiment. Further, the curved shaping of the connection pins 17a provides them with resilience like a spring, ensuring reliable contact with the connection terminals 9 of the package 1.

Using the connection pins 17a, the package 1 may be required to be fixed to the adapter 3c by some means. In such a case, the holding portion includes the fixing means to hold or fix the semiconductor package 1 on the adapter 3c. Such fixing means may, for example, be a pair of hooks 55 provided at the end faces (or the upper surfaces) of the adapter body 13 so as to face each other, as shown in FIG. 14B. In this case, the package 1 can be fixed to the adapter 3c by hooking and pressing the hooks 55 onto the upper surface of the package 1. Guides 57 and 59 may be provided on both sides of each hook 55 in order to position the package 1, as shown in FIG. 14B.

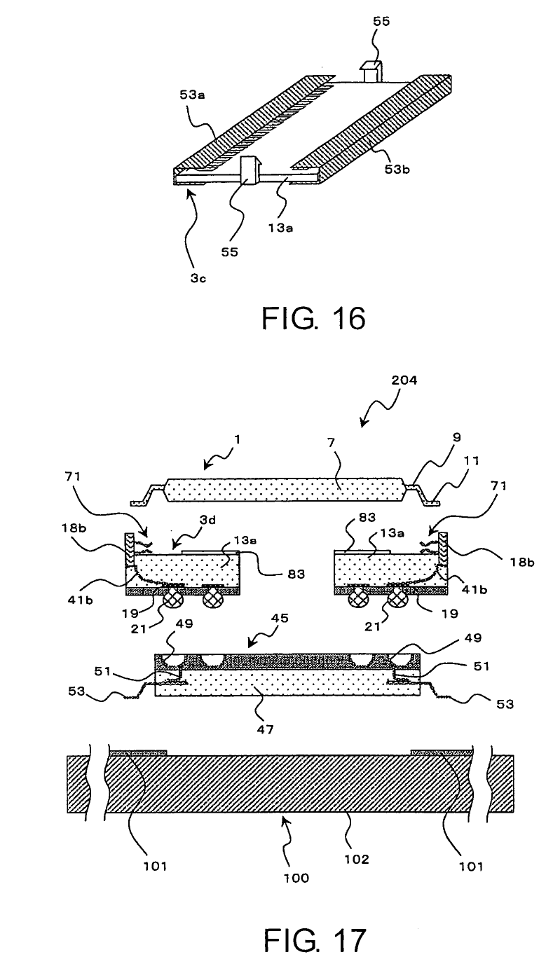

Alternatively, the fixing means may be U-shaped fixtures 53a and 53b arranged to cover the edges of the adapter body 13, as shown in FIG. 15 and FIG. 16. In this case, the package 1 can be fixed to the adapter 3c by sliding the fixtures 53a and 53b in the directions as indicated by arrows E1 and E2 of FIG. 15, respectively, with the connection terminals 9 of the package 1 being in contact with the connection pins 17a of the adapter 3c, so that the adapter 3c is partly covered with these fixtures together with the connection terminals 9. The fixtures 53a and 53b may be combined with the hooks 55 as illustrated in FIG. 16. The fixtures 53a and 53b may be made of an insulating material.

In the fourth embodiment, the shape of the socket is determined corresponding to the shape of the adapter 3c. In the structure as shown in FIG. 13, for example, the socket 5 has the same configuration as that of the first embodiment, whereas in the structure as shown in FIG. 15, the socket 45 has the same configuration as that of the third embodiment.

According to the fourth embodiment, as described above, the electronic device 203 has the package 1 which is a semiconductor package such as a TSOP type package, the adapter 3c, the socket 5 (or 5a or 45), and the wiring board 100, and is designed such that the package 1 can be mounted on the wiring board 100 via the socket 5 (or 5a or 45) after connecting the connection terminals 9 to the connection pins 17a of the adapter 3c. Therefore, the fourth embodiment provides beneficial effects similar to those of the first embodiment.

Further, according to the fourth embodiment, the adapter 3c has connection pins 17a with a shape like a plate curved upward. This makes it possible to electrically connect the package 1 and the adapter 3c even if the spacing between the connection terminals 9 of the package 1 is as small as making it difficult to connect the connection terminals 9 to the connection pins 17 if the connection pins 17 are shaped according to the first embodiment.

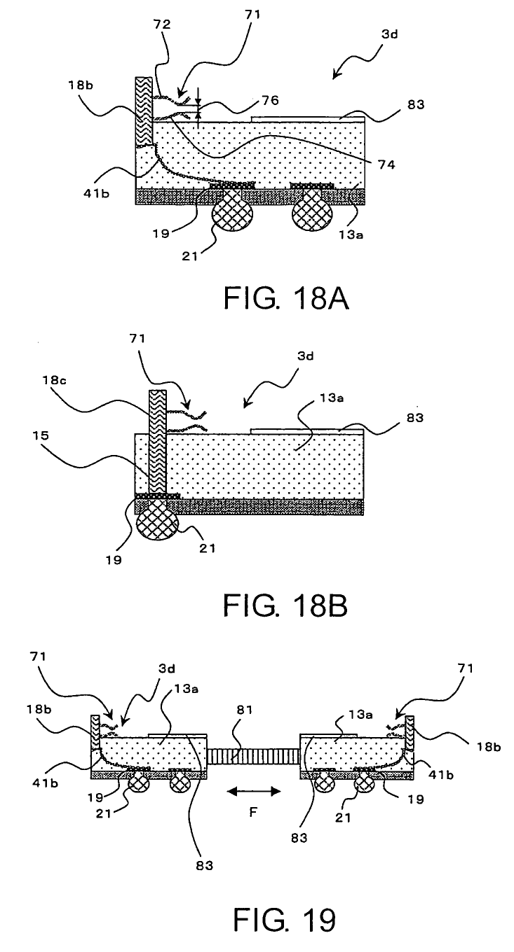

Next, a fifth embodiment of the invention will be described with reference to FIG. 17, FIGS. 18A and 18B, and FIG. 19. In the description of the fifth embodiment below, elements having the same functions as those of the first to fourth embodiments are assigned with the same reference numerals and description thereof is omitted.

An electronic device 204 according to the fifth embodiment has clip-like connection pins 71 as connecting terminals of a holding portion for an adapter 3d, while an adapter body 13a is divided into two sections.

As shown in FIG. 17, the adapter body 13a of the adapter 3d has clip-like connection pins 71 as the connecting terminals of the holding portion for the package. As shown in FIG. 18A, each of the connection pins 71 is composed of an upper leaf spring-like pin 72 (first spring-like terminal) having a plane curved downward (toward the adapter body 13a), a lower leaf spring-like pin 74 (second spring-like terminal) provided below the upper pin 72 (between the upper pin 72 and the adapter body 13a) and having a plane curved upward (toward the upper pin 72), and a conducting member 18b for fastening the ends of the upper pin 72 and lower pin 74.

The distance 76 between the upper pin 72 and the lower pin 74 is set slightly smaller than the thickness of the connection terminal 9 of the package 1. Therefore, the connection terminal 9 is held between the upper pin 72 and the lower pin 74 so that the lower surface of the upper pin 72 and the upper surface of the lower pin 74 come into contact with the connection terminal 9, whereby the connection pin 71 and the connection terminal 9 are electrically connected and fixed together.

Thus, the connection pin 71 and the connection terminal 9 are electrically connected at two electrical points by clipping the connection terminal 9 between the upper pin 72 and the lower pin 74, achieving higher reliability in connection than the connection at one contact point.

Further, the connection pins 71 are arranged in two rows opposing each other, and the adapter body 13a is separated into two sections along the direction of arrangement of the connection pins 71. Therefore, the adapter 3d and the package 1 can be connected to each other by holding the package 1 between the two sections of the adapter body 13a and clipping the connection terminals 9 on the opposite sides of the package 1 between the opposing connection pins 71.

The adapter body 13a is further provided thereon with a height adjusting pad 83. This configuration further ensures the stability during the connection.

As shown in FIG. 18A, the connection pins 71 and the solder balls 21 are connected by means of internal wiring lines 41b, in the same manner as in the adapter 3b. Alternatively, as shown in FIG. 18B, a conducting member 18c may be provided in each of the through hole 15 to be connected with the solder ball 21 via the terminal 19, in the same manner as in the adapter 3.

The adapter 3d may be provided with hooks 55 and guides 57, 59 as shown in FIG. 14B. This configuration further ensures the stability during the connection.

Further, as shown in FIG. 19, a slide rod 81 may be provided to couple the two sections of the adapter body 13a and to adjust the distance between the two sections of the adapter body 13a. The slide rod 81 is extendable and retractable in the directions indicated by arrows F of FIG. 19. This configuration improves the convenience and stability during the connection.

According to the fifth embodiment, as described above, the electronic device 204 has the package 1 which is a semiconductor package such as a TSOP type package, the adapter 3d, the socket 45, and the wiring board 100, and is designed such that the package 1 can be mounted on the wiring board 100 via the socket 45 after connecting the connection terminals 9 of the package 1 to the connection pins 71 of the adapter 3d. Therefore, the fifth embodiment provides beneficial effects similar to those of the first embodiment.

Although the description of the embodiments above has been made on the case in which the present invention is applied to a TSOP (Thin Small Outline Package) type package mounted on a wiring board 100, the present invention is not limited to this in any way, but is applicable to any other semiconductor packages using plate-shaped terminals which need to be mounted with the use of a socket.

It is apparent that the present invention is not limited to the above embodiments, but may be modified and changed without departing from the scope and spirit of the invention.

What is claimed is:

1. An adapter used for mounting a semiconductor package having plate-shaped terminals on a board by means of a socket, the adapter comprising:
an adapter body having a plate-like shape;
a holding portion which holds the semiconductor package on a first surface of the adapter body to be electrically connected to the terminals of the semiconductor package; and
first terminals provided on a second surface of the adapter body and electrically connected to the holding portion,
the adapter being mountable on the board via the socket by inserting the first terminals into the socket.

2. The adapter as claimed in claim 1, wherein the holding portion comprises connecting terminals each of which has a pillar-like shape with a cutout portion in a side face thereof, and
the semiconductor package and the adapter are mutually electrically connected by fitting the terminals of the semiconductor package in the cutout portions of the connecting terminals.

3. The adapter as claimed in claim 2, wherein the adapter body has through holes into which the connecting terminals are inserted.

4. The adapter as claimed in claim 1, wherein the first terminals comprise solder balls.

5. The adapter as claimed in claim 1, wherein the holding portion comprises connecting terminals to be connected to the terminals of the semiconductor package respectively, and wherein the first terminals are arranged at positions, on a plane, offset toward the inside of the adapter body relative to the corresponding connecting terminals of the holding portion.

6. The adapter as claimed in claim 1, wherein the holding portion comprises:
plate-shaped terminals curved upward to be connectable to the terminals of the semiconductor package; and
hooks provided on the first surface to fix the semiconductor package to the adapter body,
wherein the semiconductor package is fixed to the adapter body by bringing the plate-shaped terminals into contact with the terminals of the semiconductor package and fitting the hooks on the semiconductor package.

7. The adapter as claimed in claim 1, wherein the holding portion comprises;
plate-shaped terminals curved upward to be connectable to the terminals of the semiconductor package; and
fixtures arranged to cover the plate-shaped terminal and parts of the adapter body for fixing the semiconductor package to the adapter body,
wherein the semiconductor package is fixed to the adapter body by bringing the plate-shaped terminals into contact with the terminals of the semiconductor package and covering the part of the adapter body with the fixtures.

8. The adapter as claimed in claim 1, wherein the holding portion comprises:
connecting terminals which includes first spring-like terminals and second spring-like terminals corresponding to one another,
each of the first spring-like terminals having a leaf spring-like shape and contactable with the corresponding terminal of the semiconductor package at its lower surface; and
each of the second spring-like terminals having a leaf spring-like shape and provided between the corresponding first spring-like terminal and the first surface of the adapter to be contactable with the corresponding terminal of the semiconductor package at its upper surface, and
wherein the semiconductor package is held by holding the terminals of the semiconductor package between the first spring-like terminals and the second spring-like terminals.

9. The adapter as claimed in claim 8, being divided into a plurality of sections.

10. The adapter as claimed in claim 9, being divided into two sections along a direction in which the terminals of the semiconductor package are arranged.

11. The adapter as claimed in claim 10, comprising a slide rod for adjusting a distance between the divided adapter sections.

12. A socket provided on a board for mounting the adapter as claimed in claim 1 on the board, the socket comprising:
second terminals provided on a first surface of a socket body and electrically connected to the first terminals of the adapter; and
third terminals electrically connected to the second terminals and connectable to the board.

13. An electronic device comprising:
a semiconductor package having plate-shaped terminals;
an adapter arranged to be electrically connectable to the semiconductor package;
a socket arranged to be electrically connectable to the adapter; and
a board arranged to be electrically connectable to the socket,
wherein the adapter comprises:
a holding portion which holds the semiconductor package on a first surface of the adapter body to be electrically connected to the terminals of the semiconductor package; and
first terminals provided on a second surface of the adapter body and electrically connected to the holding portion, and
the socket comprises:
second terminals provided on a first surface of a socket body and electrically connected to the first terminals of the adapter; and
third terminals provided on a second surface of the socket body and electrically connected to the second terminals and connectable to the board.

14. The electronic device as claimed in claim 13, wherein:
the holding portion comprises connecting terminals each of which has a pillar shape with a cutout portion in a side face thereof; and
the semiconductor package and the adapter are mutually electrically connected by fitting the terminals of the semiconductor package in the cutout portions of the connecting terminals of the holding portion.

15. The electronic device as claimed in claim 13, wherein the first terminals comprise solder balls, and the second terminals comprise hole-shaped terminals each having a hole for accommodating the corresponding solder ball.

16. The electronic device as claimed in claim 15, wherein the first terminals are arranged at positions, on a plane, offset toward the inside of the adapter relative to the corresponding connecting terminals of the holding portion.

17. The electronic device as claimed in claim 13, wherein the holding portion comprises:
plate-shaped terminals curved upward to be contactable to the terminals of the semiconductor package; and
hooks provided on the first surface of the adapter body to fix the semiconductor package to the adapter body.

18. The electronic device as claimed in claim 13, wherein the holding portion comprises;
plate-shape terminals curved upward to be contactable with the terminals of the semiconductor package; and
fixtures arranged to cover parts of the adapter body.

19. The electronic device as claimed in claim 13, wherein the holding portion comprises:
connecting terminals which includes first spring-like terminals and second spring-like terminals corresponding to one another,
each of the first spring-like terminals having a leaf spring-like shape and contactable with the corresponding terminal of the semiconductor package at its lower surface; and
each of the second spring-like terminals having a leaf spring-like shape and provided between the corresponding first spring-like terminal and the first surface of the adapter to be contactable with the corresponding terminal of the semiconductor package at its upper surface.

20. The electronic device as claimed in claim 13, wherein the third terminals comprise either solder balls or lead terminals.
